(19) United States
(12) Patent Application Publication
(10) Pub. No.: US 2024/0178036 A1
(43) Pub. Date: May 30, 2024

(54) DEVICE AND METHOD FOR ALIGNING LIGHT-EMITTING DIODES

(71) Applicant: Century Technology (Shenzhen) Corporation Limited, Shenzhen (CN)

(72) Inventors: Hsin-Chieh Wu, New Taipei (TW); Deng-Kai Chang, New Taipei (TW); Tai-Hsing Lee, New Taipei (TW); Sung-Nan Cheng, New Taipei (TW)

(21) Appl. No.: 18/522,527

(22) Filed: Nov. 29, 2023

(30) Foreign Application Priority Data
Nov. 30, 2022 (CN) 202211528562.4

(51) Int. Cl. H01L 21/68; H01L 21/683; H01L 25/075

(52) U.S. Cl. CPC H01L 21/68; H01L 21/6835; H01L 25/0753; H01L 2221/68309

(57) ABSTRACT

A device for aligning light-emitting diodes (LEDs) by using a carrier substrate is provided. The carrier substrate defines a plurality of positioning grooves, and each positioning groove is configured for accommodating one of the LEDs. The device includes a carrying part for carrying the carrier substrate, a vibration part connected to the carrying part and for vibrating the carrier substrate, and a magnetic generator on a side of the carrier substrate away from the positioning grooves. A method for aligning LEDs is also provided.

### FIELD

The subject matter herein generally relates to the field of display, specifically to devices for aligning light-emitting diodes (LEDs) and methods for aligning LEDs.

### BACKGROUND

With the development of display technology, the requirement for the resolution of the display panel is getting higher and higher. Micro LEDs have become an important breakthrough in improving the resolution of display panels due to their extremely small size (usually less than 100 μm). Mass transfer technology is gradually being widely used as a batch transfer technology for small-sized micro-LEDs. However, how to neatly arrange a large number of scattered micro-LEDs after detaching from a growth substrate to facilitate mass transfer is still a problem that needs to be overcome.

Therefore, there is room for improvement in the art.

### BRIEF DESCRIPTION OF DRAWINGS

Implementations of the present disclosure will now be described, by way of embodiment, with reference to the attached figures.

FIG. 1 is a structural view illustrating a device for aligning LEDs according to an embodiment of the present disclosure.

FIG. 2 is a partial cross-sectional view along line II-II of the device in FIG. 1.

FIG. 3 is a flow chart illustrating a method for aligning LEDs according to an embodiment of the present disclosure.

FIG. 4 is a flow chart illustrating steps after block S3 of the method in FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale, and the proportions of certain parts may be exaggerated to better illustrate details and features of the present disclosure.

The term “comprising” when utilized, means “including, but not necessarily limited to;” it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.” The term “circuit” is defined as an integrated circuit (IC) with a plurality of electric elements, such as capacitors, resistors, amplifiers, and the like.

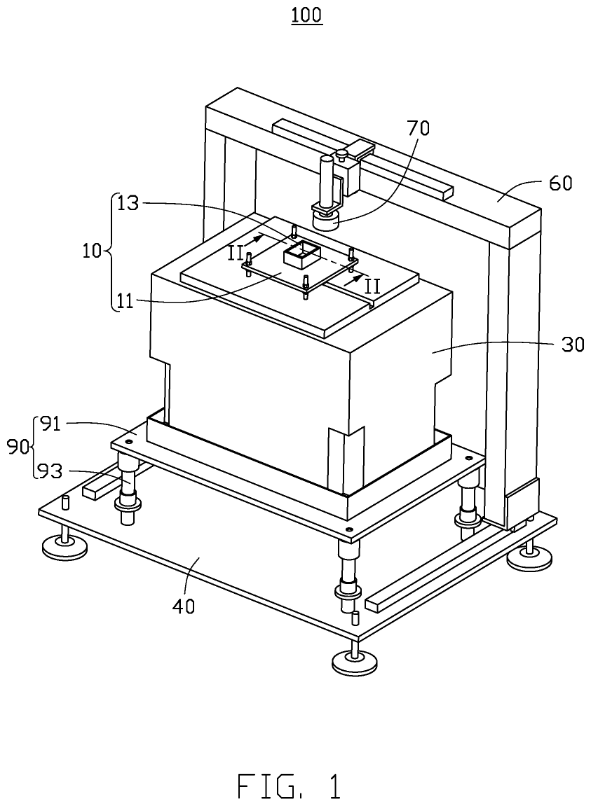

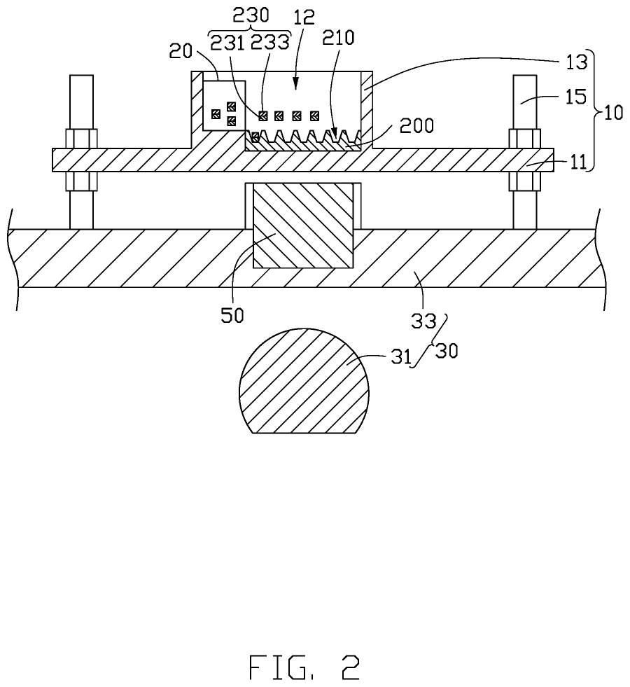

A device for aligning light-emitting diodes (LEDs) is disclosed according to an embodiment of the present disclosure. As shown in FIG. 1 and FIG. 2, the device 100 includes a carrying part 10, a vibration part 30, and a magnetic generator 50. The carrying part 10 is configured to carry a carrier substrate 200 and a plurality of LEDs 230 randomly loaded on the carrier substrate 200. The carrier substrate 200 defines a plurality of positioning grooves 210, and each positioning groove 210 is configured to accommodate one of the LEDs 230. The vibration part 30 is connected to the carrying part 10. The vibration part 30 is configured for vibrating the carrier substrate 200 so that each LED 230 falls into a corresponding one of positioning grooves 210. The magnetic generator 50 is on a side of the carrier substrate 200 away from the positioning grooves 210. The magnetic generator 50 is configured to generate a magnetic field to attract and fix the LEDs 230 falling into the corresponding positioning grooves 210.

In one embodiment, the carrier substrate 200 can be made of a material with certain rigidity. The positioning grooves 210 are arrayed on the carrier substrate 200, and each positioning groove 210 is configured for accommodating one LED 230. The carrier substrate 200 is configured for arranging the LEDs 230. By setting the number of positioning grooves 210 and the distance between adjacent two positioning grooves 210, the LEDs 230 can be arranged according to requirements, to facilitate subsequent massive transfer. That is, the carrier substrate 200 is a transfer carrier through which the arrayed LEDs 230 can be transferred to a circuit substrate of an electronic device using the LEDs 230. The circuit substrate is, for example, a thin film transistor (TFT) array substrate of a display panel.

In one embodiment, the LEDs 230 are micro-LEDs. Each LED 230 includes an electrode portion 231 and a light emitting portion 233. The electrode portion 231 is made of a ferromagnetic material, which can obtain magnetism under a magnetic field, or itself has magnetism and can be adsorbed under a magnetic field, thereby realizing the orientation of the LEDs 230. That is, each electrode portion 231 faces the bottom of a corresponding positioning groove 210, and the light emitting portion 233 faces the opposite direction.

The carrying part 10 includes a bottom plate 11 and a blocking plate 13 connected to the bottom plate 11. The bottom plate 11 is configured to carry the carrier substrate 200, and the blocking plate 13 is configured to limit a position of the carrier substrate 200 and a moving range of the LEDs 230. Specifically, the blocking plate 13 is substantially perpendicular to the bottom plate 11. The blocking plate 13 surrounds and cooperates with the bottom plate 11 to define a receiving space 12. After the carrier substrate 200 is placed in the receiving space 12, the edge of the carrier substrate 200 happens to be in contact with the blocking plate 13 and is thus limited to a predetermined position of the bottom plate 11 by the blocking plate 13. That is, the blocking plate 13 can be designed according to the size of the carrier substrate 200, so that the carrier substrate 200 can be limited to the preset position by the blocking plate 13. When the LEDs 230 are provided onto the carrier substrate 200, the LEDs 230 are limited in the receiving space 12 by the blocking plate 13, and will not be separated from the carrier substrate 200 when the carrier substrate 200 is vibrated.

The blocking plate 13 is integrally formed with the bottom plate 11. In other embodiments, the size and position of the blocking plate 13 can be adaptively adjusted according to the size of the carrier substrate 200. For example, the blocking plate 13 can include spare plates of different sizes, or the blocking plate 13 is a telescopic structure and the like.

The bottom plate 11 is fixed on the vibration part 30 by a connector 15. Specifically, the connector 15 may include a plurality of support columns, one end of each support column is fixed on the vibration part 30, and the other end of each support column is connected to the bottom plate 11, so that the bottom plate 11 is not in direct contact with the vibration part 30, thereby leaving space for placing the magnetic generator 50.

As shown in FIG. 2, the vibration part 30 includes a voice coil motor 31 and a housing 33. The housing 33 is fixedly connected to the connector 15. The voice coil motor 31 is in the housing 33 for controlling the moving direction of LEDs 230. Specifically, the vibration of the voice coil motor 31 can drive the housing 33 to vibrate, so that the carrier substrate 200 and the carrying part 10 which is stationary relative to the housing 33 vibrate along with the housing 33. When the carrier substrate 200 vibrates, the LEDs 230 on the carrier substrate 200 are also driven by the carrier substrate 200, and start to vibrate. Different from the vibration of the carrier substrate 200 driven by the voice coil motor 31, since the LEDs 230 are not fixed on the carrier substrate, when the carrier substrate 200 vibrates, the LEDs 230 first remain stationary under the action of inertia, and then is collided with the carrier substrate 200, thereby causing displacement. Under the action of gravity, the LEDs 230 continuously fall onto the carrier substrate 200 and are collided with the carrier substrate 200 to be displaced again. The voice coil motor 31 can adjust the vibration amplitude and vibration frequency of the housing 33, thereby driving the carrier substrate 200 to vibrate according to certain rules, so that the LEDs 230 can move in different directions under different vibration rules.

The device 100 further includes a feeding box 20 for accommodating the LEDs 230 and for pouring the LEDs 230 onto the carrier substrate 200. Specifically, the feeding box 20 is in the receiving space 12 and fixed on the blocking plate 13. In other embodiments, the feeding box 20 may not be in contact with the carrying part 10, as long as the feeding box 20 is on a side of the bottom plate 11 for carrying the carrier substrate 200.

In one embodiment, the magnetic generator 50 is on a side of the housing 33 adjacent to the carrying part 10 and between the bottom plate 11 and the housing 33. The magnetic generator 50 can generate a magnetic field to attract the LEDs 230. The magnetic generator 50 can be driven by current to control the strength of the magnetic field, so that the LEDs 230 falling into the positioning grooves 210 can be fixed in the positioning grooves 210 under the magnetic field. Since the LEDs 230 that has not fallen into the positioning grooves 210 are far away from the magnetic generator 50 and receive a weak magnetic force, they can still move on the surface of the carrier substrate 200 under the action of the vibration part 30 until they fall into the positioning grooves 210.

The magnetic generator 50 is partially embedded in the housing 33 to be fixed relative to the carrying part 10, and maintain a relative distance from the carrier substrate 200 when vibrating, thereby providing stable magnetic force to the LEDs 230 falling into the positioning grooves 210. In other embodiments, the magnetic generator 50 may be between the bottom plate 11 and the carrier substrate 200.

The device 100 further includes a camera 70, and the camera 70 is on the side of the carrier part 10 for carrying the carrier substrate 200, and is configured to obtain position information of the LEDs 230 on the carrier substrate 200. Specifically, the device 100 further includes a base 40 and a bracket 60. The base 40 is configured to carry the vibration part 30 and the bracket 60. The camera 70 is on the bracket 60, and aligned with the position of the bottom plate 11 where the carrier substrate 200 is placed, so as to acquire an image of the surface of the carrier substrate 200. By analyzing the image of the surface of the carrier substrate 200, it can be determined whether the LEDs 230 poured on the carrier substrate 200 and moved under the driving of the vibration part 30 fall into the positioning grooves 210. Therefore, it is judged whether the alignment of the LEDs 230 is completed.

As shown in FIG. 1, the device 100 further includes a tilting platform 90. The tilting platform 90 is on a side of the vibration part 30 away from the magnetic generator 50. The tilting platform 90 is configured to tilt the vibration part 30 to drive the carrier substrate 200 to tilt, thereby changing the moving direction of the LEDs 230 on the carrier substrate 200. Specifically, the tilting platform 90 includes a support platform 91 and a plurality of tilting columns 93. One end of each tilting column 93 is connected to the base 40, and the other end of each tilting column 93 is connected to the support platform 91. The side of the support platform 91 away from the base 40 carries the vibration part 30. The tilting columns 93 are retractable structures. By adjusting the length of each tilting column 93, the vibration part 30 can be tilted, and then the carrier substrate 200, which is relatively stationary to the vibration part, can be tilted. After the carrier substrate 200 is tilted, the LEDs 230 poured on the carrier substrate 200 moves in the tilted direction under the action of gravity. By adjusting the tilt angle of the carrier substrate 200, the moving direction of the LED 230 can be controlled. Therefore, with the vibration part 30, the moving speed of the LEDs 230 is accelerated, so that the moving direction is accurate.

The vibration part 30 can vibrate the LEDs 230 on the carrier substrate 200, so that the LEDs 230 fall into the positioning grooves 210, the magnetic generator 50 can adsorb the LEDs 230 that fall into the positioning grooves 210, thereby preventing the LEDs from coming out of the positioning grooves 210. Through the cooperation of the vibration part 30 and the magnetic generator 50, the LEDs 230 can be arranged on the carrier substrate 200 to facilitate the subsequent mass transfer process.

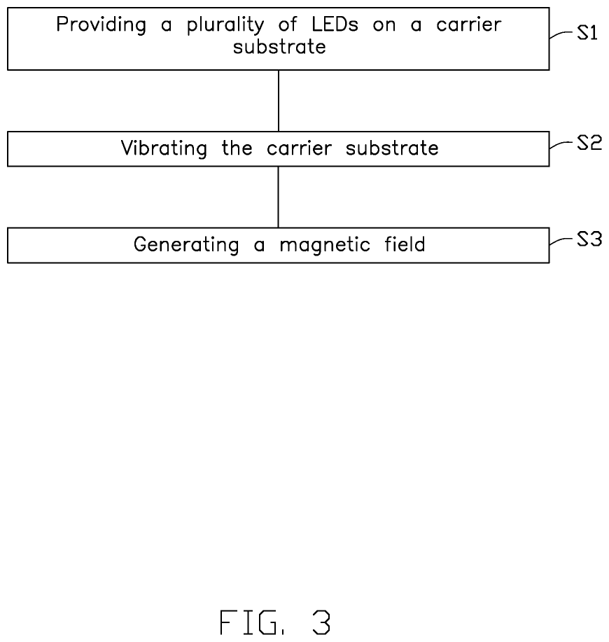

A method for aligning LEDs is disclosed. The method is provided by way of embodiment, as there are a variety of ways to carry out the method. The method described below can be carried out using the configurations illustrated in FIG. 1 and FIG. 2 for example, and various elements of these figures are referenced in explaining the method. Each block in this method represents one or more processes, methods, or subroutines, carried out in the method. Additionally, the illustrated order of blocks is by example only and the order of the blocks can change. The method can begin at block S1 of FIG. 3.

In block S1, a plurality of LEDs is provided on a carrier substrate. The carrier substrate defines a plurality of positioning grooves, and each of the positioning grooves is configured to accommodate one of the LEDs.

In block S2, the carrier substrate is vibrated so that the LEDs fall into the positioning grooves.

In block S3, a magnetic field is generated on a side of the carrier substrate away from the positioning grooves to fix the LEDs falling into the positioning groove.

The method will be described below in conjunction with the device 100 in the embodiment of the present disclosure. In other embodiments, the method may also be implemented by other alignment devices.

In one embodiment, in block S2 the vibration frequency and vibration amplitude of the carrier substrate 200 are adjusted to adjust the moving direction of the LEDs 230. Specifically, when the carrier substrate 200 vibrates, the LEDs 230 on the carrier substrate 200 are driven by the carrier substrate 200, and start to vibrate. When the carrier substrate 200 vibrates with different vibration amplitudes and vibration frequencies, the LEDs 230 can move in different directions under different vibration rules.

In one embodiment, in block S2, the carrier substrate 200 is tilted and vibrated to control the LEDs 230 to move in the direction in which the carrier substrate 200 is tilted. Specifically, the carrier substrate 200 can be directly tilted to cause the LEDs 230 move in an inclined direction under the action of gravity, thereby speeding up the moving speed of the LEDs 230. By adjusting the tilt direction of the carrier substrate 200, the moving direction of the LEDs 230 can be easily controlled.

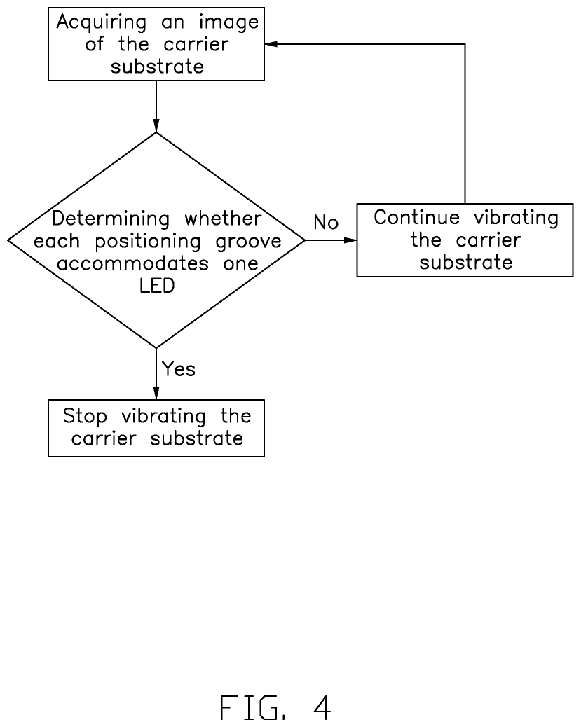

As shown in FIG. 4, after block S3, an image of the carrier substrate 200 is acquired, and it is determined whether each of the positioning grooves 210 accommodates one of the LEDs 230. If so, stop vibrating the carrier substrate 200. If not, continue to vibrate the carrier substrate 200, and repeatedly determine whether each of the positioning grooves 210 accommodates one of the LEDs 230. Specifically, by detecting the position information of the LEDs 230, it is confirmed whether the alignment of LEDs 230 is completed. By acquiring the image of the carrier substrate 200, it can be seen whether each positioning groove 210 is covered by a LED 230. During a specific operation, the vibration can be stopped first, and then the image on the carrier substrate 200 can be acquired, and according to the positions of the positioning grooves 210 not filled by the LEDs 230, the moving direction of the LEDs 230 is set.

In the method provided in the embodiment of the present disclosure, by vibrating the carrier substrate 200, the LEDs 230 can fall into the positioning grooves 210, and by generating a magnetic field, the LEDs 230 falling into the positioning groove 210 can be adsorbed and fixed, thereby realizing the alignment of the light-emitting diodes 230 and facilitating the mass transfer process.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A device configured for aligning a plurality of light-emitting diodes (LEDs) by using a carrier substrate, the carrier substrate defining a plurality of positioning grooves, each of the plurality of positioning grooves being configured to accommodate one of the plurality of LEDs, the device comprising:
a carrying part configured to carry the carrier substrate;
a vibration part connected to the carrying part, the vibration part being for vibrating the carrier substrate; and
a magnetic generator on a side of the carrier substrate away from the plurality of positioning grooves, the magnetic generator being for generating a magnetic field.

2. The device according to claim 1, wherein the vibration part comprises a voice coil motor for controlling a moving direction of the plurality of LEDs.

3. The device according to claim 1, wherein the carrying part comprises a bottom plate and a blocking plate connected to the bottom plate, the bottom plate is configured to carry the carrier substrate, and the blocking plate is configured to fix the carrier substrate and limit a moving range of the plurality of LEDs.

4. The device according to claim 3, wherein the vibration part comprises a housing and a voice coil motor in the housing, and the housing is fixedly connected to the bottom plate.

5. The device according to claim 4, wherein the bottom plate is spaced apart from the housing, the magnetic generator is between the bottom plate and the housing.

6. The device according to claim 5, wherein the magnetic generator is partially embedded in the housing.

7. The device according to claim 1, further comprising a feeding box, wherein the feeding box is configured for providing the plurality of LEDs to the carrier substrate.

8. The device according to claim 1, further comprising a camera, wherein the camera is on a side of the carrying part for carrying the carrier substrate, and is configured to acquire position information of the plurality of LEDs on the carrier substrate.

9. The device according to claim 1, further comprising a tilting platform, wherein the tilting platform is on a side of the vibration part away from the magnetic generator, and is configured to tilt the vibration part.

10. The device according to claim 9, wherein the tilting platform comprises a support platform and a plurality of tilting columns connected to the support platform, the support platform is configured to carry the vibration part, and each of the plurality of tilting columns is retractable.

11. A method for aligning light-emitting diodes (LEDs), comprising:
providing a plurality of LEDs on a carrier substrate, the carrier substrate defining a plurality of positioning grooves, and each of the plurality of positioning grooves being configured to accommodate one of the plurality of LEDs;
vibrating the carrier substrate so that the plurality of LEDs is accommodated in the plurality of positioning grooves; and
generating a magnetic field on a side of the carrier substrate away from the plurality of positioning grooves to magnetically attract the plurality of LEDs in the plurality of positioning grooves.

12. The method according to claim 11, wherein vibrating the carrier substrate further comprises:
adjusting a vibration frequency of the carrier substrate and a vibration amplitude of the carrier substrate to adjust a moving direction of the plurality of LEDs.

13. The method according to claim 11 further comprising:
acquiring an image of the carrier substrate, determining whether each of the plurality of positioning grooves accommodates the one of the plurality of LEDs, and vibrating the carrier substrate until each of the plurality of positioning grooves accommodates the one of the plurality of LEDs.

14. The method according to claim 11 further comprising:
tilting the carrier substrate, and vibrating the carrier substrate to move the plurality of LEDs in a direction in which the carrier substrate is tilted.
